(19) United States
(12) Patent Application Publication
(10) Pub. No.: US 2011/0265857 A1
(43) Pub. Date: Nov. 3, 2011

(54) Monolithic integration of bypass diodes with a thin film solar module

(75) Inventors: Chiou Fu Wang, Yonghe City (TW); Huo-Hsien Chiang, Taipei (TW)

(73) Assignee: DuPont Apollo Ltd.

(21) Appl. No.: 13/064,983

(22) Filed: Apr. 29, 2011

Related U.S. Application Data
(60) Provisional application No. 61/330,569, filed on May 3, 2010.

(51) Int. Cl. H01L 31/05; H01L 31/18

(52) U.S. Cl. 136/249; 438/59; 257/E31.124

(57) ABSTRACT

A solar module with a bypass diode integrated therein, fabricated on the basis of the standard thin film solar module. By connecting a series of p-n junction to a non-functional p-n junction in anti-parallel, the non-functional p-n junction in the standard thin film solar module is used as the bypass diode. Hence no additional bypass diode is needed in the design.

### FIELD OF THE INVENTION

The invention relates generally to a thin film solar module and, more particularly, to a thin film solar module with a bypass diode integrated therein.

### BACKGROUND OF THE INVENTION

A solar module is generally composed of many solar cells. Solar cells are typically modeled as diodes that respond to illumination by becoming forward biased and establishing a voltage across the cell. For supplying larger power, solar cells are usually connected in series.

FIG. 1 shows a conventional thin film solar module with a series of solar cells. The solar module 70′ comprises of a substrate 10, first conductive layers 21, semiconductor layers 31, the second conductive layers 41, and two contacts 51 and 52, wherein the first conductive layers 21 and the second conductive layers 41 act as front electrodes and back electrodes, respectively. A solar cell in the solar module 70′ comprises a semiconductor layer 31, a first conductive layer 21, and a second conductive layer 41, wherein the semiconductor layer 31 is sandwiched by the first conductive layer 21 and the second conductive layer 41. Each of the semiconductor layers 31 has a p-n junction formed by an n-doped region and a p-doped region. Alternatively, each of the semiconductor layers 31 may include a p-i-n junction formed by a p-doped region, intrinsic semiconductor region, and a n-doped region. The two contacts 51 and 52 are respectively a p-contact formed on the back electrode connected to the p-doped region in the semiconductor layer 31 of one solar cell and an n-contact formed on the back electrode connected to the n-doped region in the semiconductor layer 31 of another solar cell. The two contacts 51 and 52 are formed for connecting to a load (not shown). The p-n junctions in the semiconductor layers 31 are connected in series, which means the n-doped region (p-doped region) in one semiconductor layer 31 is electrically connected to the p-doped region (n-doped region) in an adjacent semiconductor layer 31 through the electrodes. The structure of the solar module is accomplished through standard process of fabrication of semiconductors, which is already known in the art and is not described in detail in the specification.

During the fabrication of a thin film solar module, a process called “edge isolation” is performed to isolate the edge portions from the main body of the solar module. The isolated edge portions (the portions at the outer sides of isolation trenches 43 as shown in FIG. 1) are usually of undesired property so that they need to be isolated from the series of solar cells and are thus wasted in the conventional solar module. Sometimes the edge portions of the solar modules are cut and discarded.

As shown in FIG. 1, except for the last solar cell in the series (the solar cell at the right side in FIG. 1), the back electrode of any one of the solar cells is connected to the front electrode of the adjacent solar cell. Through the configuration, when connecting to a load (not shown), the internal current in the solar module 70′ flows along the dashed line in FIG. 1. It shall be noted that due to the structure fabricated by the standard process, the p-n junction in the semiconductor layer 31 below the p-contact does not act as a solar cell and is non-functional in the solar module 70′. Generally, the non-functional p-n junction in the semiconductor layer 31 is wasted in the conventional solar module.

For protecting the solar modules from damage, a bypass diode is usually connected across a solar module. Conventionally, in order to ensure a shaded or failed solar module is not the bottleneck of the solar system, each module usually comes with an externally connected bypass diode. However, the externally connected bypass diode adds undesirable cost to the solar module.

Therefore, there exists a need for providing a solar module with a bypass diode monolithically integrated therein such that no externally connected diode or additional discrete diode is needed in the module.

### SUMMARY OF THE INVENTION

In one aspect, a solar module with a bypass diode monolithically integrated therein is provided. The solar module comprises: a substrate; a plurality of first conductive layers formed on the substrate; a plurality of semiconductor layers formed on the first conductive layers, wherein the plurality of semiconductor layers each comprises a p-n junction, and wherein the p-n junctions are electrically connected in series; a plurality of second conductive layers formed on the semiconductor layers; a first contact and a second contact connected to two of the second conductive layers, wherein the p-n junctions electrically coupled between the first contact and the second contact function as a series of solar cells and one of the rest of the p-n junctions functions as the bypass diode; and a conductor connecting the series of solar cells to the bypass diode in anti-parallel.

In another aspect, a method of forming solar module with a bypass diode monolithically integrated therein is provided. The method comprises: providing a substrate; forming a plurality of first conductive layers on the substrate; forming a plurality of semiconductor layers on the first conductive layers, wherein the plurality of semiconductor layers each comprises a p-n junction, and wherein the p-n junctions are electrically connected in series; forming a plurality of second conductive layers on the semiconductor layers; forming a first contact and a second contact connected to two of the second conductive layers, wherein the p-n junctions electrically coupled between the first contact and the second contact function as a series of solar cells and one of the rest of the p-n junctions functions as the bypass diode; and providing a conductor connecting the series of solar cells to the bypass diode in anti-parallel.

### BRIEF DESCRIPTION OF THE DRAWING

FIG. 1 is a side cross-sectional view illustrating a conventional thin film solar module;

FIG. 2 is a schematic electrical circuit showing that a solar cell assembly is connected in anti-parallel to a bypass diode;

FIG. 3 is a side cross-sectional view showing the connection between a series of solar cells and a integrated bypass diode;

FIGS. 4-8 are side cross-sectional views illustrating the fabricating process of a solar module in accordance with the embodiment of the present invention;

FIG. 9 is a top view of the solar module in accordance with the embodiment of the present invention.

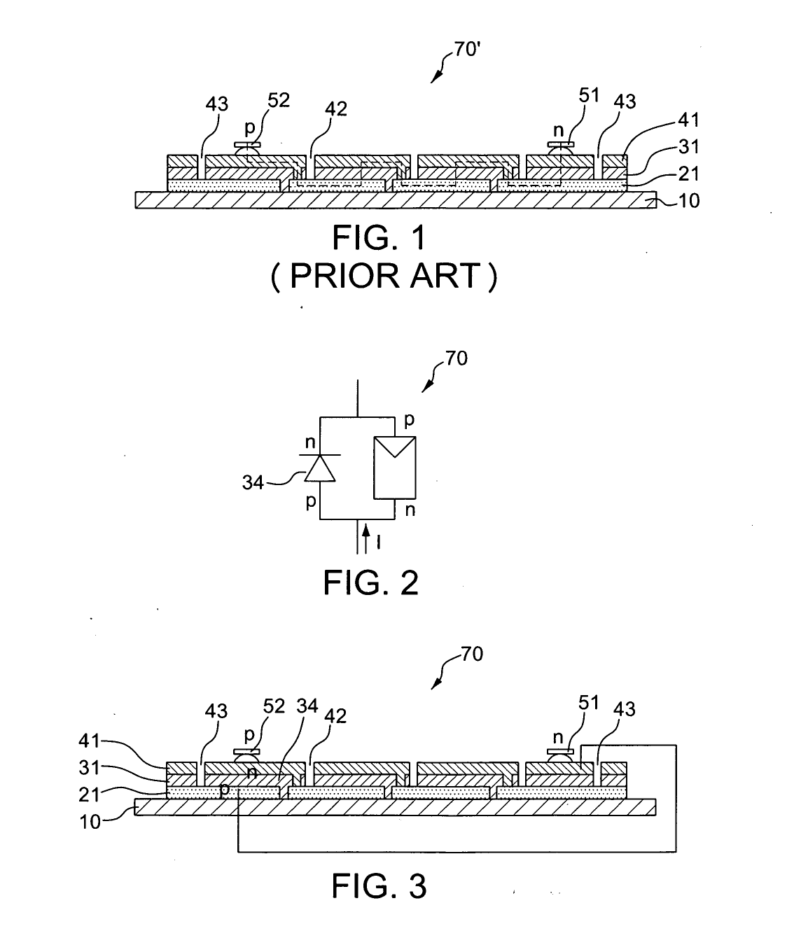

### DETAILED DESCRIPTION OF THE INVENTION

The object of the invention is to utilize the unused (non-functional) p-n junction in the solar cell of the solar modules as a bypass diode. As shown in FIG. 3, to achieve the object of the invention, an electrical connection, represented as the line connecting from the second conductive layer 41 to the first conductive layer 21, between the n-doped region in the semiconductor layer 31 below the n-contact and the p-doped region in the semiconductor layer 31 below the p-contact is needed. By the connection, the configuration as shown in FIG. 2 is achieved, in which the series of solar cell and the bypass diode 34 are connected in an anti-parallel configuration such that the bypass diode 34 is reverse biased when the solar cells are illuminated.

To achieve the object of the invention, a preferred embodiment of the solar module with a bypass diode integrated therein is provided by performing the following fabricating process.

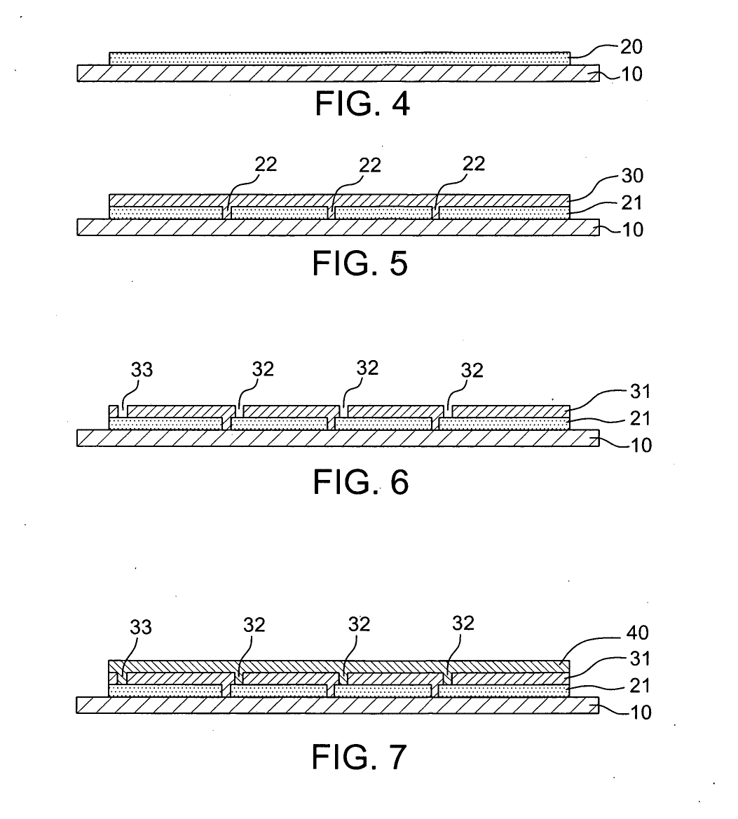

FIGS. 4-8 are schematic diagrams illustrating the fabricating process of a solar module 70 in accordance with the preferred embodiment of the invention, in which a bypass diode 34 is integrated in the solar module 70.

As shown in FIG. 4, a substrate 10 is provided. To allow the sunlight pass through the substrate 10, a transparent material such as glass, for example, is used as the substrate 10. The first conductive layer 20 is formed, by a deposition process, on the substrate 10. The deposition process may be implemented by plasma-enhanced chemical vapor deposition (PECVD) or other deposition techniques, which can consist of several different deposition techniques.

Subsequently, as shown in FIG. 4, first trenches 22 are formed in the first conductive layer 20 by etching away parts of the conductive layer 20. The etching process may be implanted by, for example, laser scribing, chemical etching, mechanical scribing, ion beam writing, or other related techniques. Since the deposition process and the etching process are conventional techniques which are known in the art, they are not described in detail in the following steps.

After the etching process, the first conductive layer 20 was divided into several first conductive layers 21 to be used as the front electrodes of the solar cells in the solar module 70. The number of the first conductive layers 21 is determined based on the desired number of the solar cells in series. In the exemplary embodiment, for easy illustration, four first conductive layers are formed.

In FIG. 5, a semiconductor layer 30 is then deposited over the first conductive layers 21 such that the semiconductor layer 30 is formed on the first conductive layers 21 and fills the first trenches 22. Similarly, to allow the sunlight pass through the first conductive layers 21, a conductive and transparent material such as transparent conductive oxide (TCO) may be used to form the first conductive layers 21.

The semiconductor layer 30 may be any kind of semiconductor materials suitable for using as solar cell, wherein the semiconductor layer 30 is doped to form an n-doped region and a p-doped region. In the preferred embodiment, an amorphous silicon is utilized for forming the semiconductor layer 30 and the semiconductor layer 30 is doped such that the bottom side of the semiconductor layer 30 is a p-doped region and the upper side of the semiconductor layer 30 is an n-doped region. In addition, an intrinsic semiconductor region would be inserted between the p-doped region and the n-doped region in the case of amorphous silicon solar cells. Alternatively, the semiconductor layer 30 may be doped in an opposite manner. Moreover, if the sunlight comes in from the other side, the position of the p-doped region and the n-doped region formed in the semiconductor layer 30 may be exchanged according to a different design.

In FIG. 6, second trenches 32 are formed in the semiconductor layer 30 by an etching process such that some portions of the first conductive layers 21 are exposed. The semiconductor layer 30 was divided into several semiconductor layers 31 by the second trenches 32. A contact trench 33 is formed at the edge of the solar module, as shown at the left side of the solar module 70. The contact trench 33 is prepared for the connection between the series of solar cells and the bypass diode.

As shown in FIG. 7, a second conductive layer 40 is deposited over the semiconductor layers 31 such that the second conductive layer 40 is formed on the semiconductor layers 31 and fills the second trenches 32 and the contact trench 33. The material of the second conductive layer 40 may be copper or any other transparent or opaque materials of desired conductivity.

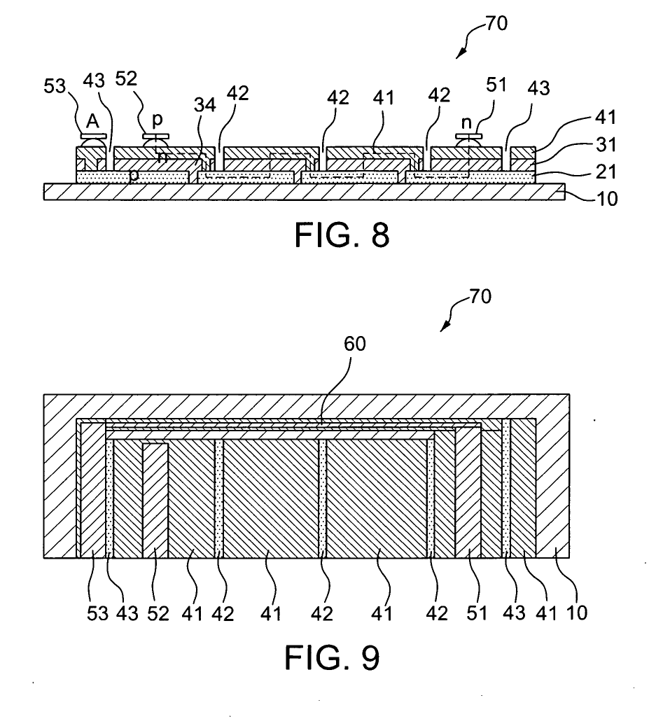

In FIG. 8, third trenches 42 are then formed in the semiconductor layers 31 and the second conductive layers 40 so as to expose some portions of the surface of the first conductive layers 21. In addition, edge isolation is performed by forming the isolation trenches 43 at the edges of the solar module 70. Through the edge isolation, the edge portions of the solar cells at the two sides of the solar module 70 are isolated from the series of solar cells. Since the isolated portions are usually of undesired property, usually they are not utilized for acting as solar cells or bypass diodes.

Subsequently, a first contact 51 and a second contact 52 are then formed on two of the second conductive layers 41 as the contacts of the series of solar cells. When the two contacts are connected to a load (not shown), the internal current in the solar module 70 flows along the dashed line in FIG. 8, which does not flow through the semiconductor layer below the second contact 52. Therefore, in the solar module 70, the p-n junction in the semiconductor below the second contact 52 is an “unused” or “non-functional” p-n junction, which is not used for a solar cell.

In the subject invention, the unused p-n junction of the semiconductor layer is utilized as a bypass diode by connecting to the series of the solar cells in an anti-parallel configuration. As shown in FIG. 8, a third contact 53 is formed on the second conductive layer 41 on the isolated portion adjacent to the second contact 52. The third contact 53 is electrically connected to the p-doped region of the semiconductor layer 31 below the second contact 52 through the second conductive layer 41 and the first conductive layer 21.

FIG. 9 is a top-view of the solar module 70 shown in FIG. 8. In the preferred embodiment of the subject invention, a conductor, more specifically a conductive ribbon 60 is formed between the third contact 53 and the first contact 51 for connecting the two contacts electrically. By the connection, the unused p-n junction below the second contact 52 is now used as a bypass diode 34 which is connected in anti-parallel to the series of solar cells in the solar module 70.

It is appreciated that although the unused p-n junction below the second contact 52 is electrically connected in parallel with the series of solar cells through the ribbon 60, the first contact 51, and the third contact 53, one skilled in the art will know that the connection may be in any desired form so as to achieve the electrical circuit shown in FIG. 2.

While the illustrative embodiment of the invention has been shown and described, numerous variations and alternate embodiment will occur to those skilled in the art. Such variations and alternate embodiments are contemplated, and can be made without departing from the spirit and scope of the invention as defined in the appended claims.

What is claimed is:

1. A solar module with a bypass diode monolithically integrated therein, comprising:
a substrate;
a plurality of first conductive layers formed on the substrate;
a plurality of semiconductor layers formed on the first conductive layers, wherein the plurality of semiconductor layers each comprises a p-n junction, and wherein the p-n junctions are electrically connected in series;
a plurality of second conductive layers formed on the semiconductor layers;
a first contact and a second contact connected to two of the second conductive layers, wherein the p-n junctions electrically coupled between the first contact and the second contact function as a series of solar cells and one of the rest of the p-n junctions functions as the bypass diode; and
a conductor connecting the series of solar cells to the bypass diode in anti-parallel.

2. The solar module of claim 1, further comprising a third contact electrically coupled to the first conductive layer connected to the p-n junction which functions as the bypass diode.

3. The solar module of claim 2, wherein the third contact is formed adjacent to the second contact, and wherein the bypass diode is below the second contact.

4. The solar module of claim 3, wherein the conductor is connected between the first contact and the third contact.

5. The solar module of claim 4, wherein the third contact is formed on an edge portion isolated from the series of solar cells in the solar module.

6. A method of forming a solar module with a bypass diode monolithically integrated therein, comprising:
providing a substrate;
forming a plurality of first conductive layers on the substrate;
forming a plurality of semiconductor layers on the first conductive layers, wherein the plurality of semiconductor layers each comprises a p-n junction, and wherein the p-n junctions are electrically connected in series;
forming a plurality of second conductive layers on the semiconductor layers;
forming a first contact and a second contact connected to two of the second conductive layers, wherein the p-n junctions electrically coupled between the first contact and the second contact function as a series of solar cells and one of the rest of the p-n junctions functions as the bypass diode; and
providing a conductor connecting the series of solar cells to the bypass diode in anti-parallel.

7. The method of claim 6, further comprising forming a third contact electrically coupled to the first conductive layer connected to the p-n junction which functions as the bypass diode.

8. The method of claim 7, wherein the third contact is formed adjacent to the second contact, and wherein the bypass diode is below the second contact.

9. The method of claim 8, wherein the conductor is connected between the first contact and the third contact.

10. The method of claim 9, wherein the third contact is formed on an edge portion isolated from the series of solar cells in the solar module.
